(19) United States
(12) Patent Application Publication
(10) Pub. No.: US 2026/0012008 A1
(43) Pub. Date: Jan. 8, 2026

(54) ELECTROSTATIC DISCHARGE PROTECTION DEVICE

(71) Applicant: RichWave Technology Corp., Taipei (TW)

(72) Inventors: Ching-Yao Pai, Taipei (TW); Yu-Hung Chen, Taipei (TW)

(73) Assignee: RichWave Technology Corp., Taipei (TW)

(21) Appl. No.: 18/893,882

(22) Filed: Sep. 23, 2024

(30) Foreign Application Priority Data
Jul. 5, 2024 (TW) 113125361

(51) Int. Cl. H02H 9/04

(52) U.S. Cl. CPC H02H 9/04

(57) ABSTRACT

The disclosure provides an electrostatic discharge (ESD) protection device for protecting a core circuit coupled between a first power rail and a second power rail. The ESD protection device includes a first ESD clamp circuit, a second ESD clamp circuit, and a pull-up element. The first ESD clamp circuit is coupled between the first power rail and a common node. The second ESD clamp circuit is coupled between the common node and the second power rail. A first terminal of the pull-up element is coupled to the common node. A second terminal of the pull-up element is coupled to a signal transmission wire. The core circuit is coupled to a signal connection pad through the signal transmission wire.

### CROSS-REFERENCE TO RELATED APPLICATION

This application claims the priority benefit of Taiwan application serial no. 113125361, filed on Jul. 5, 2024. The entirety of the above-mentioned patent application is hereby incorporated by reference herein and made a part of this specification.

### BACKGROUND

### Technical Field

The disclosure relates to an electronic circuit, and in particular to an electrostatic discharge (ESD) protection device.

### Description of Related Art

The energy release phenomenon of static electricity is called electrostatic discharge (ESD). When an ESD stress is applied to a core circuit (a functional circuit) within an integrated circuit, the ESD stress may damage the core circuit. How to prevent the ESD stress from damaging the core circuits is one of many technical issues in the field of electronic circuit technology.

In particular, in the initial state of the system, the system power supply voltage (such as VDD) may rise later than the signal voltage, causing electrostatic discharge charges on the signal connection pads to leak to power connection pads through pull-up elements.

### SUMMARY

The disclosure provides an electrostatic discharge (ESD) protection device to prevent an ESD stress from damaging a core circuit, and to prevent a charge of a signal connection pad from leaking to a power connection pad through a pull-up element and a power rail in the initial state of the system.

In an embodiment of the disclosure, the ESD protection device is configured to protect the core circuit coupled between a first power rail and a second power rail. The ESD protection device includes a first ESD clamp circuit, a second ESD clamp circuit, and the pull-up element. The first ESD clamp circuit is coupled between the first power rail and a common node. The second ESD clamp circuit is coupled between the common node and the second power rail. A first terminal of the pull-up element is coupled to the common node. The second terminal of the pull-up element is coupled to a signal transmission wire. The core circuit is coupled to the signal connection pad through the signal transmission wire.

Based on the above, the first terminal of the pull-up element in various embodiments of the disclosure is coupled to the common node between the first ESD clamp circuit and the second ESD clamp circuit. When an electrostatic discharge event occurs on the signal connection pad, the ESD clamp circuit and the pull-up element can immediately guide an ESD charge of the signal connection pad to the power rail to prevent the ESD stress from damaging the core circuit. In the initial state of the system, when the rising time point of a system power voltage (such as VDD) of the power rail is later than the rising time point of a voltage of the signal connection pad so that the voltage of the power rail is lower than the voltage of the signal connection pad, the ESD clamp circuit can prevent the charge of the signal connection pad from leaking to the power rails.

To make the aforementioned more comprehensible, several embodiments accompanied with drawings are described in detail as follows.

### BRIEF DESCRIPTION OF THE DRAWINGS

FIG. 1 is a circuit block schematic diagram of an integrated circuit according to an embodiment of the disclosure.

FIG. 2A is a circuit block diagram of an integrated circuit according to another embodiment of the disclosure.

FIG. 2B is a circuit block diagram of an integrated circuit according to yet another embodiment of the disclosure.

FIG. 3 is a circuit block diagram of an integrated circuit according to another embodiment of the disclosure.

FIG. 4 is a schematic circuit block diagram of a bidirectional switch element according to an embodiment of the disclosure.

FIG. 5 is a schematic circuit block diagram of a bidirectional switch element according to another embodiment of the disclosure.

FIG. 6 is a circuit block diagram of the control circuit according to an embodiment of the disclosure.

FIG. 7 is a schematic circuit block diagram of an electrostatic discharge (ESD) protection device according to another embodiment of the disclosure.

FIG. 8 is a schematic circuit block diagram of the bidirectional switch element according to another embodiment of the disclosure.

FIG. 9 is a schematic circuit block diagram of the bidirectional switch element according to another embodiment of the disclosure.

FIG. 10 is a schematic circuit block diagram of the bidirectional switch element according to another embodiment of the disclosure.

FIG. 11 is a circuit block diagram of an integrated circuit according to yet another embodiment of the disclosure.

FIG. 12 is a circuit block diagram of the integrated circuit according to another embodiment of the disclosure.

FIG. 13 is a schematic circuit block diagram of the pull-up element according to an embodiment of the disclosure.

FIG. 14 is a schematic circuit block diagram of a pull-up element according to another embodiment of the disclosure.

FIG. 15 is a circuit block diagram of the ESD clamp circuit according to an embodiment of the disclosure.

FIG. 16 is a circuit block diagram of the ESD clamp circuit according to another embodiment of the disclosure.

FIG. 17 is a circuit block diagram of the ESD clamp circuit according to yet another embodiment of the disclosure.

FIG. 18 is a schematic circuit block diagram of the pull-up element and the pull-down element according to an embodiment of the disclosure.

FIG. 19 is a schematic circuit block diagram of the pull-up element and the pull-down element according to yet another embodiment of the disclosure.

FIG. 20 is a schematic circuit block diagram of the pull-up element and the pull-down element according to yet another embodiment of the disclosure.

FIG. 21 is a schematic circuit block diagram of the pull-up element and the pull-down element according to yet another embodiment of the disclosure.

FIG. 22 is a schematic circuit block diagram of the pull-up element and the pull-down element according to another embodiment of the disclosure.

### DESCRIPTION OF THE EMBODIMENTS

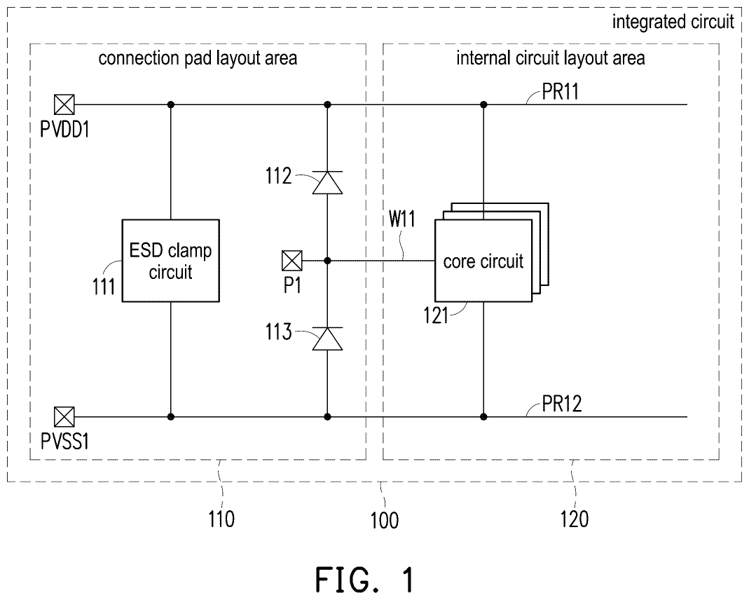

A term “couple (or connected)” used in the full text of the disclosure (including the claims) refers to any direct and indirect connections. For example, if a first device is described to be coupled (or connected) to a second device, it is interpreted as that the first device is directly connected to the second device, or the first device is indirectly connected to the second device through other devices or connection means. The terms “first”, “second”, and the like as mentioned throughout the full text of the disclosure (including the claims) are used to name the elements or to distinguish between different embodiments or scopes, rather than setting an upper or lower limit on the number of the elements or the order of the elements. Moreover, wherever possible, components/members/steps using the same referential numbers in the drawings and description refer to the same or like parts. Components/members/steps using the same referential numbers or using the same terms in different embodiments may cross-refer related descriptions. FIG. 1 is a circuit block schematic diagram of an integrated circuit 100 according to an

embodiment of the disclosure. Generally speaking, connection pads of the integrated circuit 100 may be arranged in a connection pad layout area 110, and a core circuit 121 (or referred to as an internal circuit) of the integrated circuit 100 may be arranged in an internal circuit layout area 120. A signal connection pad P1 may be, but is not limited to, a signal input pad, a signal output pad, or a bidirectional transmission signal pad. The core circuit 121 is coupled to the signal connection pad P1 through a signal transmission wire W11. A power supply voltage (such as VDD or other power supply voltage) is coupled to a power rail PR11 through a power connection pad PVDD1 to transmit a system power supply voltage (such as the VDD or other power supply voltage) to the core circuit 121 of the integrated circuit 100. A reference voltage (such as a ground voltage or other fixed voltage) is coupled to a power rail PR 12 through a power connection pad PVSS1 to transmit the reference voltage (such as the ground voltage or other fixed voltage) to the core circuit 121.

An electrostatic discharge (ESD) protection circuit is arranged in the connection pad layout area 110 and is configured near the connection pads of the integrated circuit 100 to place ESD charges of the connection pads nearby. In the embodiment shown in FIG. 1, the ESD protection circuit includes an ESD clamp circuit 111, a pull-up element 112, and a pull-down element 113. The ESD clamp circuit 111 is coupled between the power rail PR11 and the power rail PR12. This embodiment does not limit the specific implementation of the ESD clamp circuit 111, the pull-up element 112, and the pull-down element 113. When an ESD event occurs on the signal connection pad P1, the ESD protection circuit configured in the connection pad layout area 110 may guide the ESD charges on the signal connection pad P1 to the power connection pad PVDD1 or the power connection pad PVSS1 through the power rail PR11 and the power rail PR12.

For example, when an ESD positive pulse occurs in the signal connection pad P1 and the power connection pad PVDD1 is grounded (or coupled to the reference voltage or other fixed voltage, hereinafter grounded), the pull-up element 112 may be turned on to guide an ESD current from the signal connection pad P1 to the power connection pad PVDD1 through the power rail PR11. When the ESD positive pulse occurs in the signal connection pad P1 and the power connection pad PVSS1 is grounded, the pull-up element 112 may be turned on to guide the ESD current from the signal connection pad P1 to the power connection pad PVSS1 through the power rail PR11, the ESD clamp circuit 111, and the power rail PR12. When an ESD negative pulse occurs in the signal connection pad P1 and the power connection pad PVSS1 is grounded, the pull-down element 113 may be turned on to guide the ESD current from the power connection pad PVSS1 to the signal connection pad P1 through the power rail PR12. When the ESD negative pulse occurs on the signal connection pad P1 and the power connection pad PVDD1 is grounded, the pull-down element 113 may be turned on to guide the ESD current from the power connection pad PVDD1 to the signal connection pad P1 through the power rail PR12, the ESD clamp circuit 111, and the power rail PR11. The pull-up element 112 may be multiple diodes connected in the same direction in series, and the pull-down element 113 may also be multiple diodes connected in the same direction in series.

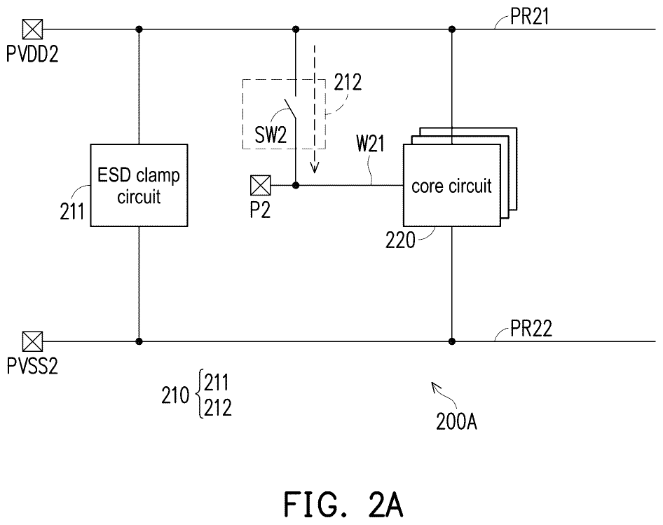

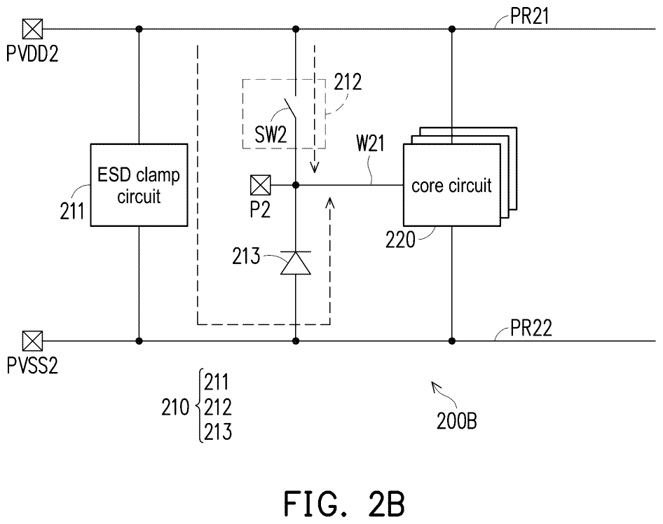

However, in an initial state of the system, a rise of the system power supply voltage (such as the VDD) of the power rail PR11 may be later than a rise of the voltage of the signal connection pad P1, causing the voltage of the power rail PR11 to be lower than the voltage of the signal connection pad P1. At this time, the charge of the signal connection pad P1 may leak to the power connection pad PVDD1 through the pull-up element 112 and the power rail PR11. FIG. 2A is a circuit block diagram of an integrated circuit 200A according to another

embodiment of the disclosure. The integrated circuit 200A shown in FIG. 2A includes an ESD protection device 210 and a core circuit 220. The core circuit 220 is coupled to a signal connection pad P2 through a signal transmission wire W21. A power rail PR21 may transmit the system supply voltage (e.g., the VDD) of a power connection pad PVDD2 to the core circuit 220. A power rail PR22 may transmit the reference voltage (e.g., the ground voltage) of a power connection pad PVSS2 to the core circuit 220. The ESD protection device 210 is used to protect the core circuit 220 coupled between the power rail PR21 and the power rail PR22. The core circuit 220, or referred to as the internal circuit, may be a main functional circuit of the integrated circuit 200A, for example, but not limited to, a radio frequency amplifier circuit, a radio frequency switch circuit, etc.

In the embodiment shown in FIG. 2A, the ESD protection device 210 includes an ESD clamp circuit 211 and a pull-up element 212 including a bidirectional switch element SW2. The ESD clamp circuit 211 is coupled between the power rail PR21 and the power rail PR22. The integrated circuit 200A shown in FIG. 2A may be deduced by referring to the relevant description of the integrated circuit 100 shown in FIG. 1, and therefore is not repeated herein.

In the embodiment shown in FIG. 2A, the pull-up element 212 may include but is not limited to the bidirectional switch element SW2. The first terminal of the bidirectional switch element SW2 is coupled to the power rail PR21, and the second terminal of the bidirectional switch element SW2 is coupled to the signal transmission wire W21. A control terminal of the bidirectional switch element SW2 is coupled to a control circuit or the reference voltage (to be described later). When no ESD event occurs (a normal operating state) on the signal connection pad P2, the control circuit (or the reference voltage) may turn off the bidirectional switch element SW2. In other words, in the initial state of the system, when a rising time point of the system power supply voltage (such as the VDD) of the power rail PR21 is later than a rising time point of the voltage of the signal connection pad P2 so that the voltage of the power rail PR21 is lower than the voltage of the signal connection pad P2, the bidirectional switch element SW2 that is turned off can prevent the charge of the signal connection pad P2 from leaking to the power rail PR21.

When the ESD event occurs, the bidirectional switch element SW2 is turned on or breakdowns to discharge the ESD current of the ESD event. The bidirectional switch element SW2 that is turned on (or breakdownd) may immediately guide the ESD charge of the signal connection pad P2 to the power rail PR21 to prevent an ESD stress from damaging the core circuit 220. When the ESD event occurs on the connection pad P2, the bidirectional switch element SW2 breakdowns to discharge the ESD current of the ESD event.

For example, when the ESD positive pulse occurs on the power connection pad PVDD2 and the signal connection pad P2 is grounded, or when the ESD negative pulse occurs on the signal connection pad P2 and the power connection pad PVDD2 is grounded (that is, when the power rail PR21 is grounded), the bidirectional switch element SW2 forms an ESD path from the power rail PR21 to the signal connection pad P2.

FIG. 2B is a circuit block diagram of an integrated circuit 200B according to yet another embodiment of the disclosure. The integrated circuit 200B shown in FIG. 2B includes the ESD protection device 210 and the core circuit 220. The core circuit 220 is coupled to the signal connection pad P2 through the signal transmission wire W21. The power rail PR21 may transmit the system supply voltage (e.g., the VDD) of power connection pad PVDD2 to the core circuit 220. The power rail PR22 may transmit the reference voltage (e.g., the ground voltage) of the power connection pad PVSS2 to the core circuit 220. The ESD protection device 210 is used to protect the core circuit 220 coupled between the power rail PR21 and the power rail PR22. The core circuit 220, or referred to as internal circuit, may be the main functional circuit of the integrated circuit 200B, for example, but not limited to, the radio frequency amplifier circuit, the radio frequency switch circuit, etc.

In the embodiment shown in FIG. 2B, the ESD protection device 210 includes the ESD clamp circuit 211, the pull-up element 212 including a bidirectional switch element SW2, and a pull-down element 213. The ESD clamp circuit 211 is coupled between the power rail PR21 and the power rail PR22. The first terminal of the pull-down element 213 is coupled to the signal transmission wire W21. The second terminal of pull-down element 213 is coupled to the power rail PR22. The integrated circuit 200B shown in FIG. 2B may be deduced by referring to the relevant description of the integrated circuit 100 shown in FIG. 1, and therefore is not repeated herein.

In the embodiment shown in FIG. 2B, the pull-up element 212 may include but is not limited to the bidirectional switch element SW2. The first terminal of the bidirectional switch element SW2 is coupled to the power rail PR21, and the second terminal of the bidirectional switch element SW2 is coupled to the signal transmission wire W21. The control terminal of the bidirectional switch element SW2 is coupled to the control circuit or the reference voltage (to be described later). When no ESD event occurs (a normal operating state) on the signal connection pad P2, the control circuit (or the reference voltage) may turn off the bidirectional switch element SW2. In other words, in the initial state of the system, when the rising time point of the system power supply voltage (such as the VDD) of the power rail PR21 is later than the rising time point of the voltage of the signal connection pad P2 so that the voltage of the power rail PR21 is lower than the voltage of the signal connection pad P2, the bidirectional switch element SW2 that is turned off can prevent the charge of the signal connection pad P2 from leaking to the power rail PR21.

When the ESD event occurs, the bidirectional switch element SW2 is turned on or breakdowns to discharge the ESD current of the ESD event. The bidirectional switch element SW2 that is turned on (or breakdownd) may immediately guide the ESD charge of the signal connection pad P2 to the power rail PR21 to prevent the ESD stress from damaging the core circuit 220. When the ESD event occurs on the connection pad P2, the bidirectional switch element SW2 breakdowns to discharge the ESD current of the ESD event.

For example, when the ESD positive pulse occurs on the power connection pad PVDD2 and the signal connection pad P2 is grounded, or when the ESD negative pulse occurs on the signal connection pad P2 and the power connection pad PVDD2 is grounded (that is, when the power rail PR21 is grounded), the bidirectional switch element SW2 forms a first ESD path from the power rail PR21 to the signal connection pad P2, and the ESD clamp circuit 211, the power rail PR22 and the pull-down element 213 together form a second ESD path from the power rail PR21 to the signal connection pad P2. An activation voltage of the first ESD path is lower than the activation voltage of the second ESD path. In this way, the integrated circuit 200B may provide two ESD discharge paths at the same time, which can improve an ESD protection capability.

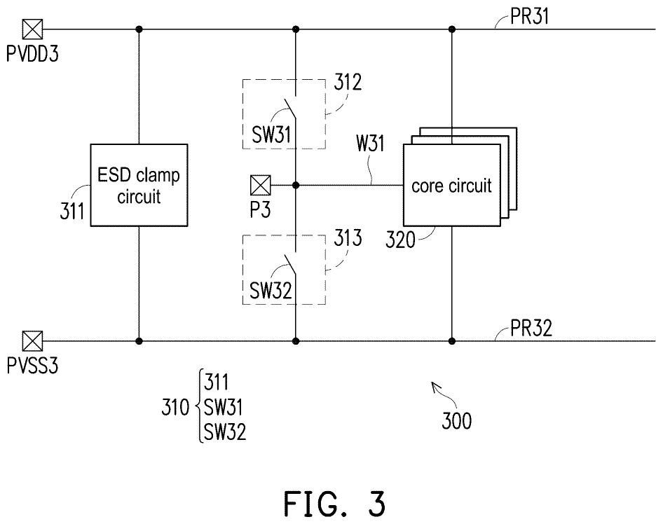

FIG. 3 is a circuit block diagram of an integrated circuit 300 according to another embodiment of the disclosure. The integrated circuit 300 shown in FIG. 3 may be deduced by referring to the relevant description of the integrated circuit 200A shown in FIG. 2A or the integrated circuit 200B shown in FIG. 2B, and therefore is not repeated herein.

In the embodiment shown in FIG. 3, a pull-up element 312 may include, but is not limited to, a bidirectional switch element SW31. A pull-down element 313 may include, but is not limited to, a bidirectional switch element SW32. The first terminal of the bidirectional switch element SW31 is coupled to a power rail PR31 to be coupled to a power connection pad PVDD3. The second terminal of the bidirectional switch element SW32 is coupled to a signal transmission wire W31 to be coupled to a signal connection pad P3. The first terminal of the bidirectional switch element SW32 is coupled to the signal transmission wire W31 to be coupled to the signal connection pad P3. The second terminal of the bidirectional switch element SW32 is coupled to a power rail PR32 to be coupled to a power connection pad PVSS3. The control terminal of the bidirectional switch element SW32 is coupled to the control circuit or the reference voltage (to be described later). When no ESD event occurs (a normal operating state) on the signal connection pad P3, the control circuit (or the reference voltage) may turn off the bidirectional switch elements SW31 and SW32. The bidirectional switch element SW31 may be used as a first ESD clamp circuit, and the bidirectional switch element SW32 may be used as a second ESD clamp circuit. In an embodiment, the number of the bidirectional switch elements SW31 and SW32 may be at least one switch transistor. Therefore, compared with the pull-up element 112 and the pull-down elements 113 and 213 in FIG. 1, FIG. 2A, or FIG. 2B, a smaller area or/and a lower component count may be used to save area. When the ESD event occurs, at least one of the bidirectional switch elements SW31 and SW32 is turned on (or breakdowns) to discharge the ESD current of the ESD event.

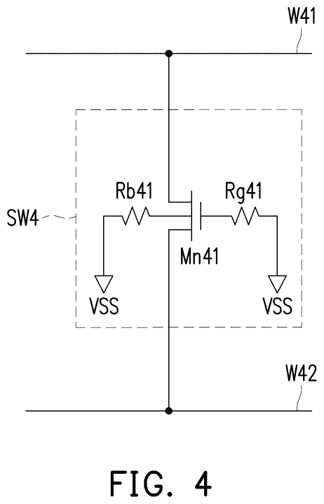

FIG. 4 is a schematic circuit block diagram of a bidirectional switch element SW4 according to an embodiment of the disclosure. The first terminal of the bidirectional switch element SW4 is coupled to a wire W41. The second terminal of the bidirectional switch element SW4 is coupled to a wire W42. In an embodiment, the first terminal of the bidirectional switch element SW4 is coupled to a higher voltage relative to the second terminal of the bidirectional switch element SW4. For example, when the bidirectional switch element SW4 shown in FIG. 4 is used as one of the many embodiments of the bidirectional switch element SW2 shown in FIG. 2A or FIG. 2B, the wire W41 and the wire W42 shown in FIG. 4 may refer to the relevant description of the power rail PR21 and the signal transmission wire W21 shown in FIG. 2A or FIG. 2B. When the bidirectional switch element SW4 shown in FIG. 4 is used as one of many embodiments of the bidirectional switch element SW31 shown in FIG. 3, the wire W41 and the wire W42 shown in FIG. 4 may refer to the relevant description of the power rail PR31 and the signal transmission wire W31 shown in FIG. 3. When the bidirectional switch element SW4 shown in FIG. 4 is used as one of many embodiments of the bidirectional switch element SW32 shown in FIG. 3, the wire W41 and the wire W42 shown in FIG. 4 may refer to the relevant description of the signal transmission wire W31 and the power rail PR32.

In the embodiment shown in FIG. 4, the bidirectional switch element SW4 includes a switch transistor Mn41, a resistor Rg41, and a resistor Rb41. The first terminal (e.g., a drain) of the switch transistor Mn41 is coupled to the wire W41. The second terminal (e.g., a source) of the switch transistor Mn41 is coupled to the wire W42. In an embodiment, the bidirectional switch element SW4 may be a field effect transistor (FET), such as but not limited to a metal oxide semi-field effect transistor (MOSFET). In an embodiment, the bidirectional switch element SW4 may be manufactured using an SOI process (silicon on insulator process). In an embodiment, the bidirectional switch element SW4 may be an N-type metal oxide semi-field effect transistor (MOSFET).

A base (bulk or body) of the switch transistor Mn41 is coupled to a reference voltage VSS (e.g., the ground voltage) through the resistor Rb41. The control terminal (e.g., a gate) of the switch transistor Mn41 is coupled to the control voltage (e.g., the reference voltage VSS or other shutdown voltage) through the resistor Rg41 to turn off the switch transistor Mn41. That is, the first terminal of the resistor Rg41 is coupled to the control terminal of the switch transistor Mn41, and the second terminal of the resistor Rg41 is coupled to the reference voltage VSS.

When no ESD event occurs (a normal operating state), the reference voltage VSS may turn off the switch transistor Mn41. When the ESD event occurs, the switch transistor Mn41 breakdowns to discharge the ESD current of the ESD event from the wire W41 to the wire W42 (or from the wire W42 to the wire W41).

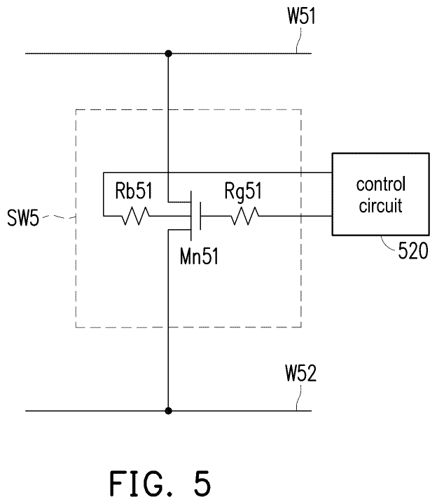

FIG. 5 is a schematic circuit block diagram of a bidirectional switch element SW5 according to another embodiment of the disclosure. The first terminal of the bidirectional switch element SW5 is coupled to a wire W51. The second terminal of the bidirectional switch element SW5 is coupled to a wire W52. The bidirectional switch element SW5 includes a switch transistor Mn51, a resistor Rg51, and a resistor Rb51. The bidirectional switch element SW5 shown in FIG. 5 may be deduced by referring to the relevant description of the bidirectional switch element SW4 shown in FIG. 4, and therefore is not repeated herein.

In the embodiment shown in FIG. 5, the ESD protection device further includes a control circuit 520, and the control terminal of the bidirectional switch element SW5 is coupled to the control circuit 520. In detail, the base of the switch transistor Mn51 is coupled to the control circuit 520 through the resistor Rb51. The first terminal of the resistor Rg51 is coupled to the control terminal (e.g., the gate) of the switch transistor Mn51, and the second terminal of the resistor Rg51 is coupled to the control circuit 520. The control terminal of the switch transistor Mn51 is coupled to the control circuit 520 through the resistor Rg51 to receive the control voltage. When the ESD event does not occur (in the normal operation), the control circuit 520 turns off the switch transistor Mn51 through the control voltage.

In some embodiments, when the ESD event occurs, the control circuit 520 turns on the switch transistor Mn51 through the control voltage to discharge the ESD current of the ESD event. Alternatively, in other embodiments, when the ESD event occurs, the control circuit 520 causes the control terminal of the switch transistor Mn51 to be in an electrically floating state, and the switch transistor Mn51 generates a coupling voltage at the control terminal due to the ESD stress, and turns on the switch transistor Mn51 to discharge the ESD current of the ESD event. In an embodiment, under the normal operation (when no ESD event occurs), the control circuit 520 may be, but is not limited to, a radio frequency (RF) switch control circuit to control the actuation of the RF switch.

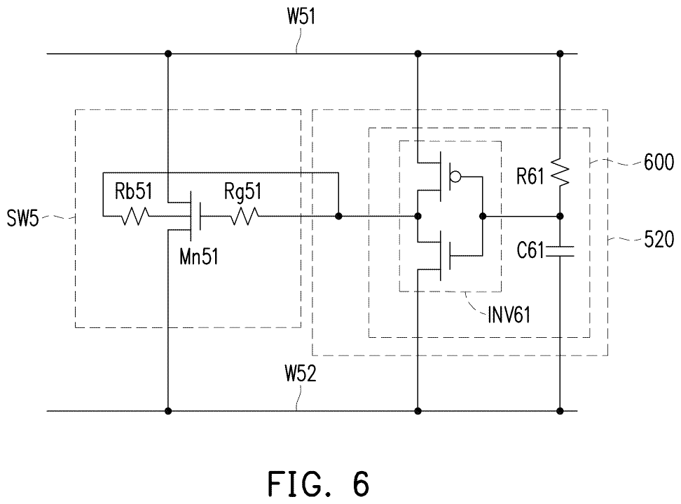

FIG. 6 is a circuit block diagram of the control circuit 520 according to an embodiment of the disclosure. The control circuit 520 shown in FIG. 6 may be used as one of many implementation examples of the control circuit 520 shown in FIG. 5. In the embodiment shown in FIG. 6, the control circuit 520 may include a detection circuit 600, and the detection circuit 600 includes an inverter INV61, a resistor R61, and a capacitor C61. An output terminal of the inverter INV61 is coupled to the resistors Rg51 and Rb51. The first terminal of the resistor R61 is coupled to the wire W51. The second terminal of the resistor R61 and the first terminal of the capacitor C61 are coupled to an input terminal of the inverter INV61. The second terminal of the capacitor C61 is coupled to the wire W52.

That is, the detection circuit 600 is coupled to the control terminal of the bidirectional switch element SW5. In detail, the base of the switch transistor Mn51 is coupled to the detection circuit 600 through the resistor Rb51, and the control terminal of the switch transistor Mn51 is coupled to the detection circuit 600 through the resistor Rg51. The detection circuit 600 may detect the voltage of the signal connection pad (for the signal connection pad, please refer to the relevant description of the signal connection pad P2 shown in FIG. 2A or FIG. 2B or the signal connection pad P3 shown in FIG. 3) to determine whether the ESD event occurs, so as to dynamically determine the voltage of the base of the switch transistor Mn51 and the voltage of the control terminal. When the ESD event occurs, the detection circuit 600 turns on the bidirectional switch element SW5. When no ESD event occurs (a normal operating state), the detection circuit 600 turns off the bidirectional switch element SW5.

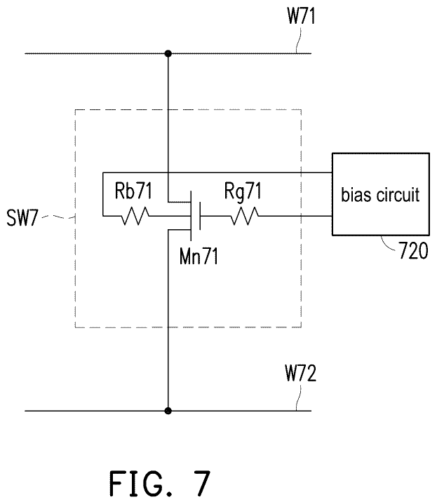

FIG. 7 is a schematic circuit block diagram of an electrostatic discharge (ESD) protection device according to another embodiment of the disclosure. In the embodiment shown in FIG. 7, the ESD protection device includes a bidirectional switch element SW7 and a bias circuit 720. The bidirectional switch element SW7 may be deduced by referring to the relevant description of the bidirectional switch element SW5 shown in FIG. 5, and therefore is not repeated herein.

In the embodiment shown in FIG. 7, the bias circuit 720 is coupled to the control terminal of the bidirectional switch element SW7. In detail, the control terminal of a switch transistor Mn71 is coupled to the bias circuit 720 through a resistor Rg71. When the ESD event occurs, the bias circuit 720 causes the control terminal of the switch transistor Mn71 to be in the electrically floating state, and the switch transistor Mn71 generates the coupling voltage at the control terminal due to the ESD stress, thereby turning on the switch transistor Mn51 to discharge the ESD current in the ESD event. When the ESD event does not occur (in the normal operation), the bias circuit 720 provides a bias voltage to the control terminal of the switch transistor Mn71 to turn off the switch transistor Mn71. The bias circuit 720 may also be coupled to the base of the bidirectional switch element SW7. Specifically, the base of the switch transistor Mn71 is coupled to the bias circuit 720 through a resistor Rb71. When the ESD event occurs, the bias circuit 720 causes the base of the switch transistor Mn71 to be in the electrically floating state. When the ESD event does not occur (in the normal operation), the bias circuit 720 provides the bias voltage to the base of the switch transistor Mn71 to appropriately turn off the switch transistor Mn71. Under normal operating conditions, the bias circuit 720 may be, but is not limited to, a low-dropout bias circuit to provide functional circuit bias for the core circuit.

Although in the embodiment shown in FIG. 4, the bidirectional switch element SW4 includes the single switch transistor Mn41, the number of switch transistors of the bidirectional switch element SW4 may be determined according to the actual design. For example, in other embodiments, the bidirectional switch element SW4 may include multiple switch transistors. The switch transistors are steaked to each other or connected in series between the wires W41 and W42.

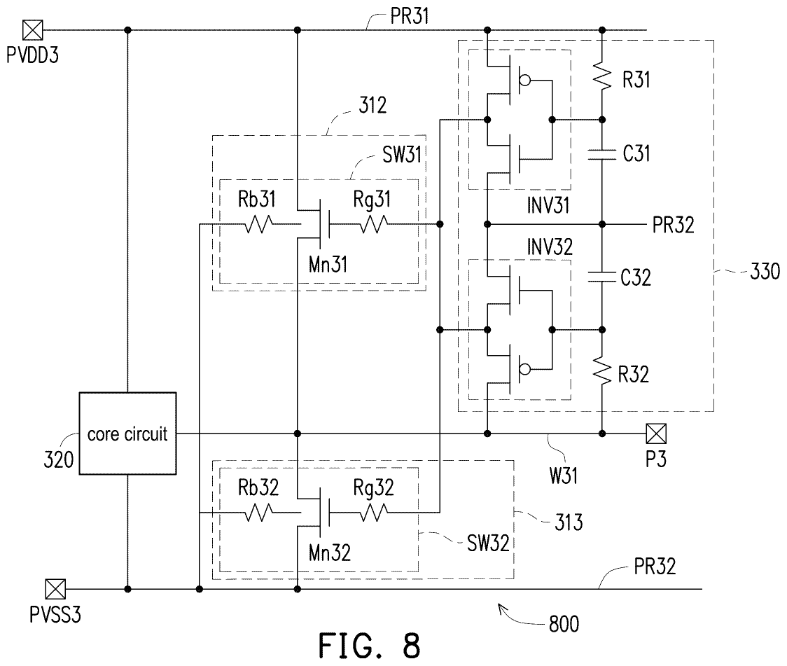

FIG. 8 is a schematic circuit block diagram of the bidirectional switch elements SW31 and SW32 according to another embodiment of the disclosure. The bidirectional switch elements SW31 and SW32 shown in FIG. 8 may be used as one of many implementation examples of the bidirectional switch elements SW31 and SW32 shown in FIG. 3. An integrated circuit 800 shown in FIG. 8 may be deduced by referring to the relevant description of the integrated circuit 300 shown in FIG. 3, and therefore is not repeated herein.

In the embodiment shown in FIG. 8, the ESD protection device further includes a control circuit 330. The pull-up element 312 includes a bidirectional switch element SW31. The bidirectional switch element SW31 further includes a switch transistor Mn31, a resistor Rg31, and a resistor Rb31. The pull-down element 313 includes the bidirectional switch element SW32. The bidirectional switch element SW32 further includes a switch transistor Mn32, a resistor Rg32, and a resistor Rb32. The base of the switch transistor Mn31 is coupled to the power rail PR32 through the resistor Rb31, and the base of the switch transistor Mn32 is coupled to the power rail PR32 through the resistor Rb32. The control terminal of the switch transistor Mn31 is coupled to the control circuit 330 through the resistor Rg31, and the control terminal of the switch transistor Mn32 is coupled to the control circuit 330 through the resistor Rg32.

The control circuit 330 includes an inverter INV31, an inverter INV32, a resistor R31, a resistor R32, a capacitor C31, and a capacitor C32. The output terminals of the inverters INV31 and INV32 are coupled to the resistors Rg31 and Rg32. The power terminal of the inverter INV31 is coupled to the power rail PR31. Reference terminals of the inverters INV31 and INV32 are coupled to the power rail PR32. The power terminal of the inverter INV32 is coupled to the signal transmission wire W31. The first terminal of the resistor R31 is coupled to the power rail PR31. The second terminal of the resistor R31 and the first terminal of the capacitor C31 are coupled to the input terminal of the inverter INV31. The second terminal of capacitor C31 is coupled to the power rail PR32. The first terminal of the resistor R32 is coupled to the signal transmission wire W31. The second terminal of the resistor R32 and the first terminal of the capacitor C32 are coupled to the input terminal of the inverter INV32. The second terminal of capacitor C32 is coupled to the power rail PR32.

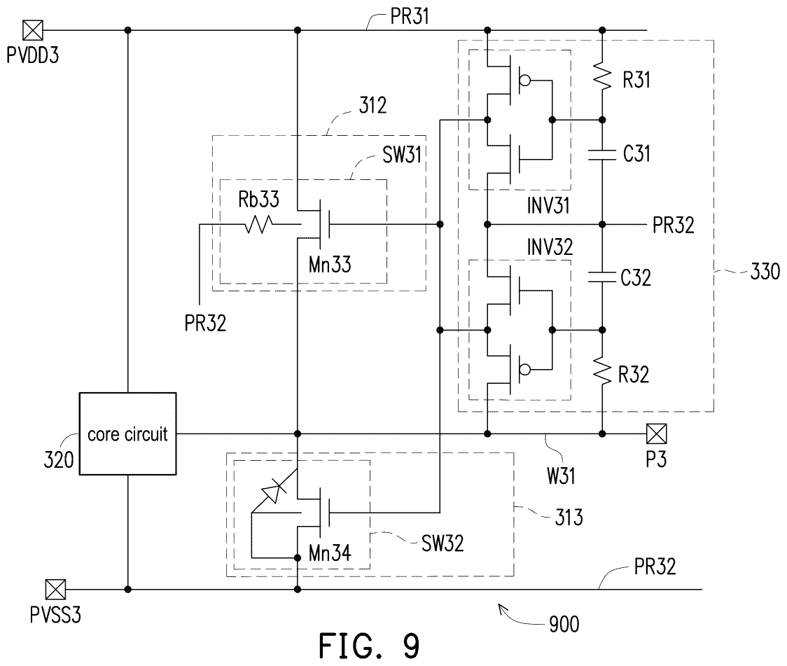

FIG. 9 is a schematic circuit block diagram of the bidirectional switch elements SW31 and SW32 according to another embodiment of the disclosure. The bidirectional switch elements SW31 and SW32 shown in FIG. 9 may be used as one of many implementation examples of the bidirectional switch elements SW31 and SW32 shown in FIG. 3. An integrated circuit 900 shown in FIG. 9 may be deduced by referring to the relevant description of the integrated circuit 800 shown in FIG. 8, and therefore is not repeated herein.

In the embodiment shown in FIG. 9, the ESD protection device further includes the control circuit 330. The bidirectional switch element SW31 includes a switch transistor Mn33 and a resistor Rb33. The bidirectional switch element SW32 includes a switch transistor Mn34. The base of the switch transistor Mn33 is coupled to the power rail PR32 through the resistor Rb33, and the base of the switch transistor Mn34 is directly coupled to the source of the switch transistor Mn34. The source of the switch transistor Mn34 is coupled to the power rail PR32. The base of the switch transistor Mn34 is further coupled to the signal transmission wire W31 through a parasitic diode. The control terminals of the switch transistors Mn33 and Mn34 are directly coupled to the output terminals of the inverters INV31 and INV32 of the control circuit 330.

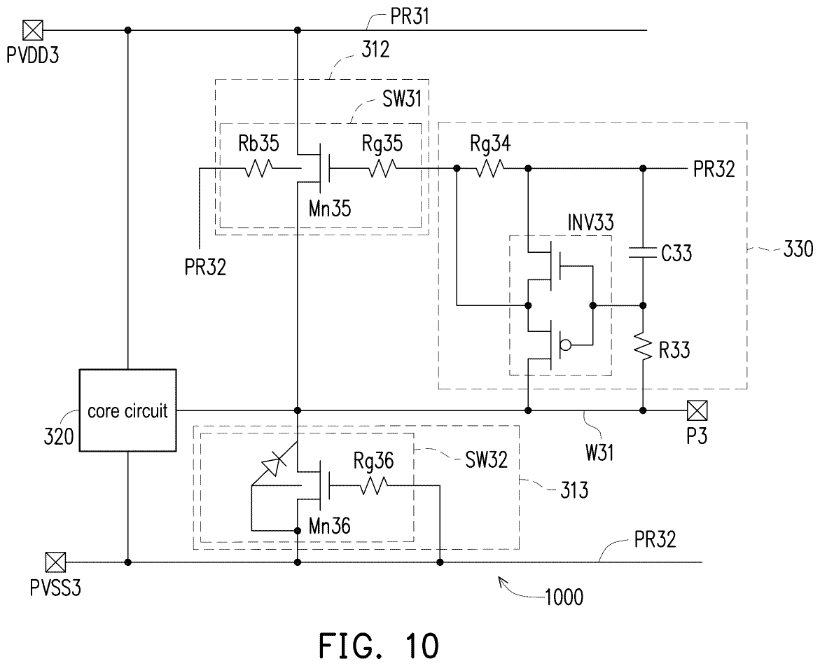

FIG. 10 is a schematic circuit block diagram of the bidirectional switch elements SW31 and SW32 according to another embodiment of the disclosure. The bidirectional switch elements SW31 and SW32 shown in FIG. 10 may be used as one of many implementation examples of the bidirectional switch elements SW31 and SW32 shown in FIG. 3. An integrated circuit 1000 shown in FIG. 10 may be deduced by referring to the relevant description of the integrated circuit 300 shown in FIG. 3, and therefore is not repeated herein.

In the embodiment shown in FIG. 10, the ESD protection device further includes the control circuit 330. The bidirectional switch element SW31 includes a switch transistor Mn35, a resistor Rg35, and a resistor Rb35. The bidirectional switch element SW32 includes a switch transistor Mn36 and a resistor Rg36. The base of the switch transistor Mn35 is coupled to the power rail PR32 through the resistor Rb35, and the base of the switch transistor Mn36 is directly coupled to the source of the switch transistor Mn36. The source of the switch transistor Mn36 is coupled to the power rail PR32. The base of the switch transistor Mn36 is further coupled to the signal transmission wire W31 through the parasitic diode. The control terminal of the switch transistor Mn36 is coupled to the power rail PR32 through the resistor Rg36. The control terminal of the switch transistor Mn35 is coupled to the control circuit 330 through the resistor Rg35.

The control circuit 330 includes an inverter INV33, a resistor R33, a resistor Rg34, and a capacitor C33. The first terminal of the resistor Rg34 is coupled to the resistor Rg35. The second terminal of resistor Rg34 is coupled to the power rail PR32. The output terminal of the inverter INV33 is coupled to the resistor Rg35. The reference terminal of the inverter INV33 is coupled to the power rail PR32. The power terminal of the inverter INV33 is coupled to the signal transmission wire W31. The first terminal of the resistor R33 is coupled to the signal transmission wire W31. The second terminal of the resistor R33 and the first terminal of the capacitor C33 are coupled to the input terminal of the inverter INV33. The second terminal of capacitor C33 is coupled to the power rail PR32.

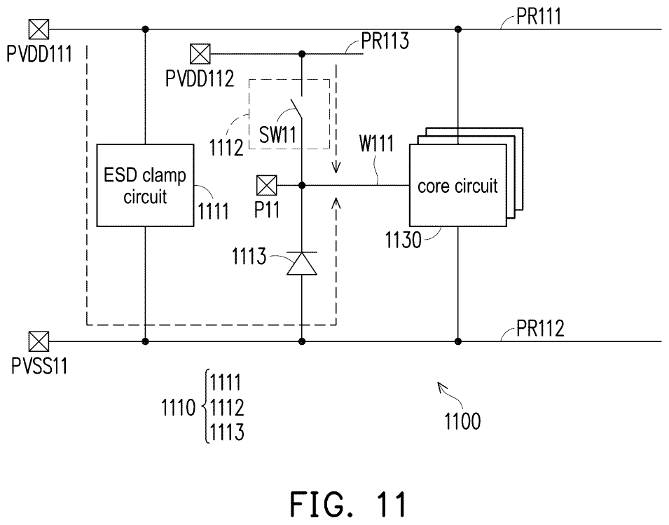

FIG. 11 is a circuit block diagram of an integrated circuit 1100 according to yet another embodiment of the disclosure. The integrated circuit 1100 shown in FIG. 11 includes an ESD protection device 1110 and a core circuit 1130. The core circuit 1130 is coupled to a signal connection pad P11 through a signal transmission wire W111. A power rail PR111 may transmit the system supply voltage (e.g., a VDD1) of a power connection pad PVDD111 to the core circuit 1130. A power rail PR112 may transmit the reference voltage (e.g., the ground voltage) of a power connection pad PVSS11 to the core circuit 1130. The ESD protection device 1110 is used to protect the core circuit 1130 coupled between the power rail PR111 and the power rail PR112.

In the embodiment shown in FIG. 11, the ESD protection device 1110 includes an ESD clamp circuit 1111, a pull-up element 1112 including a bidirectional switch element SW11, and a pull-down element 1113. The ESD clamp circuit 1111 is coupled between the power rail PR111 and the power rail PR112. The first terminal of the pull-down element 1113 is coupled to the signal transmission wire W111. The second terminal of pull-down element 1113 is coupled to the power rail PR112. The integrated circuit 1100 shown in FIG. 11 may be deduced by referring to the relevant description of the integrated circuit 100 shown in FIG. 1, and therefore is not repeated herein.

In the embodiment shown in FIG. 11, a power rail PR113 may transmit the system supply voltage (e.g., a VDD2) of a power connection pad PVDD112 to the pull-up element 1112. The pull-up element 1112 may include, but is not limited to, the bidirectional switch element SW11. The first terminal of the bidirectional switch element SW11 is coupled to the power rail PR113, and the second terminal of the bidirectional switch element SW11 is coupled to the signal transmission wire W111. The control terminal of the bidirectional switch element SW11 is coupled to the control circuit or the reference voltage. When no ESD event occurs (a normal operating state) on the signal connection pad P11, the control circuit (or the reference voltage) may turn off the bidirectional switch element SW11. In other words, in the initial state of the system, when the rising time point of the system power voltage (e.g., the VDD2) of the power rail PR113 is later than the rising time point of the voltage of the signal connection pad P11 so that the voltage of the power rail PR113 is lower than the signal connection pad P11, the bidirectional switch element SW11 that is turned off can prevent the charge of the signal connection pad P11 from leaking to the power rail PR113.

When an ESD event occurs, the bidirectional switch element SW11 is turned on or breakdowns to discharge the ESD current of the ESD event. The turned-on (or breakdownd) bidirectional switch element SW11 may instantly guide the ESD charge of the signal connection pad P11 to the power rail PR113 to prevent the ESD stress from damaging the core circuit 1130. When an ESD event occurs on the connection pad P11, the bidirectional switch element SW11 breakdowns to discharge the ESD current of the ESD event.

For example, when the ESD positive pulse occurs on the power connection pad PVDD112 and the signal connection pad P11 is grounded, or when the ESD negative pulse occurs on the signal connection pad P11 and the power connection pad PVDD112 is grounded (that is, when the power rail PR113 is grounded), the bidirectional switch element SW11 forms the ESD path from the power rail PR113 to the signal connection pad P11. When the ESD positive pulse occurs on the power connection pad PVDD111 and the signal connection pad P11 is grounded, or when the ESD negative pulse occurs on the signal connection pad P11 and the power connection pad PVDD111 is grounded (that is, when the power rail PR111 is grounded), the ESD clamp circuit 1111, the power rail PR112, and the pull-down element 1113 together form the ESD path from the power rail PR111 to the signal connection pad P11.

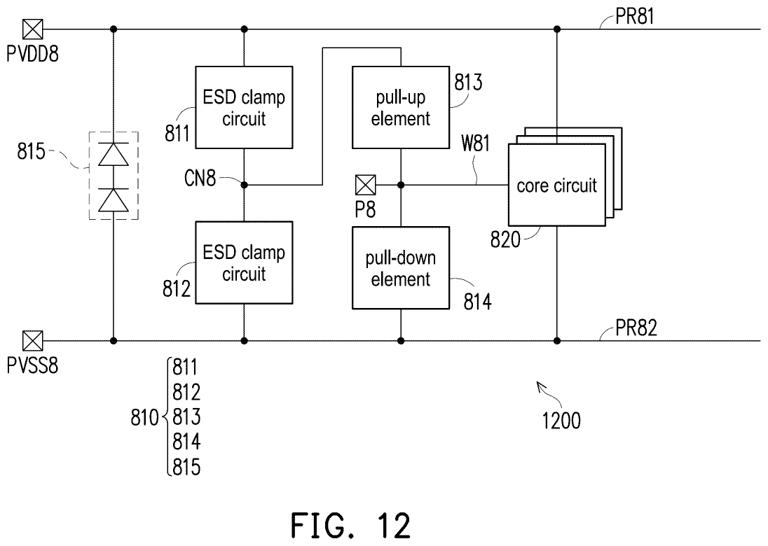

FIG. 12 is a circuit block diagram of the integrated circuit 1200 according to another embodiment of the disclosure. The integrated circuit 1200 shown in FIG. 12 includes an ESD protection device 810 and a core circuit 820. The core circuit 820 is coupled to a signal connection pad P8 through a signal transmission wire W81. A power rail PR81 may transmit the system supply voltage (e.g., the VDD or other supply voltage) from a power connection pad PVDD8 to the core circuit 820. A power rail PR82 may transmit the reference voltage (such as the ground voltage or other fixed voltage) of a power connection pad PVSS8 to the core circuit 820. The ESD protection device 810 is used to protect the core circuit 820 coupled between the power rail PR81 and the power rail PR82.

In the embodiment shown in FIG. 12, the ESD protection device 810 includes an ESD clamp circuit 811, an ESD clamp circuit 812, an ESD clamp circuit 815, a pull-up element 813, and a pull-down element 814. The ESD clamp circuit 811 is coupled between the power rail PR81 and a common node CN8. The ESD clamp circuit 812 is coupled between the common node CN8 and the power rail PR82. The first terminal of the pull-up element 813 is coupled to the common node CN8. In the embodiment shown in FIG. 12, the common node CN8 is only coupled to the ESD clamp circuit 811, the ESD clamp circuit 812, and the pull-up element 813, thereby avoiding redundant leakage paths. The second terminal of the pull-up element 813 is coupled to the signal transmission wire W81. The first terminal of the pull-down element 814 is coupled to the signal transmission wire W81. The second terminal of the pull-down element 814 is coupled to the power rail PR82. The connection methods of the pull-up elements, the pull-down elements, the power rails, the connection pads, and the ESD clamp circuits of the integrated circuit 1200 shown in FIG. 12 may be deduced by referring to the relevant description of the integrated circuit 100 shown in FIG. 1, and therefore is not repeated herein.

This embodiment does not limit the specific implementation of the ESD clamp circuits 811 and 812. The ESD clamp circuit 811 or 812 may include a conventional ESD clamp circuit or other ESD clamp circuits. When the control circuit 520 and the bidirectional switch element SW5 shown in FIG. 6 are used as one of the many embodiments of the ESD clamp circuit 811 shown in FIG. 12, the wire W51 and the wire W52 shown in FIG. 6 may be regarded as the power rail PR81 and the common node CN8 shown in FIG. 12, respectively. When the control circuit 520 and the bidirectional switch element SW5 shown in FIG. 6 are used as one of the many embodiments of the ESD clamp circuit 812 shown in FIG. 12, the wire W51 and the wire W52 shown in FIG. 6 may be regarded as the common node CN8 and the power rail PR82 shown in FIG. 12, respectively.

In the embodiment shown in FIG. 12, an operating voltage (operating range) of the pull-up element 813 is less than the system power supply voltage of the core circuit 820. For example (but not limited thereto), the operating voltage range of the pull-up element 813 may be VDD minus V811 or VDD minus V812, where VDD represents the system power supply voltage of the core circuit 820, V811 represents the operating voltage of the ESD clamp circuit 811, and V812 represents the operating voltage of the ESD clamp circuit 812. The operating voltage refers to the voltage range that may be resisted under the normal operation conditions. For example, the operating voltage may be but is not limited to 5V. In other words, under the same system power supply voltage, the operating voltage of the pull-up element 813 of FIG. 12 may be less than the operating voltage of the pull-up element 212 of FIG. 2A.

When no ESD event occurs (a normal operating state) on the signal connection pad P8, the pull-up element 813 and the pull-down element 814 are turned off. In the initial state of the system, the rising point of the system power voltage (e.g., the VDD or other power voltage) of the power rail PR81 may be later than the rising point of the voltage of the signal connection pad P8. When the voltage of the power rail PR81 is lower than the voltage of the signal connection pad P8 in the initial state of the system, the ESD clamp circuit 811 that is turned off and the pull-up element 813 may clamp the voltage of the signal connection pad P8 to prevent the charge of the signal connection pad P8 from leaking to the power rail PR81.

When the ESD event occurs, at least one of the pull-up element 813 and the pull-down element 814 is turned on (or breakdowns) to discharge the ESD current of the ESD event. The turned-on (or breakdownd) pull-up element 813 may immediately guide the ESD charge of the signal connection pad P8 to the power rail PR81, or the turned-on (or breakdownd) pull-down element 814 may immediately guide the ESD charge of the signal connection pad P8 to the power rail PR82 to prevent the ESD stress from damaging the core circuit 820.

For example, when the ESD event occurs on the signal connection pad P8, the pull-up element 813 is turned on, and the ESD current of the ESD event may pass through one of the ESD clamp circuit 811 and the ESD clamp circuit 812. Assuming that when the ESD positive pulse occurs on the power rail PR81 and the signal connection pad P8 is grounded, or when the ESD negative pulse occurs on the signal connection pad P8 and the power connection pad PVDD1 is grounded (that is, when the power rail PR81 is grounded), the ESD clamp circuit 811 and the pull-up element 813 jointly form the ESD path (the first ESD path) from the power rail PR81 to the signal connection pad P8, and the ESD clamp circuit 811, the ESD clamp circuit 812, the power rail PR82, and the pull-down element 814 jointly form another ESD path (the second ESD path) from the power rail PR81 to the signal connection pad P8. The activation voltage of the first ESD path is lower than the activation voltage of the second ESD path.

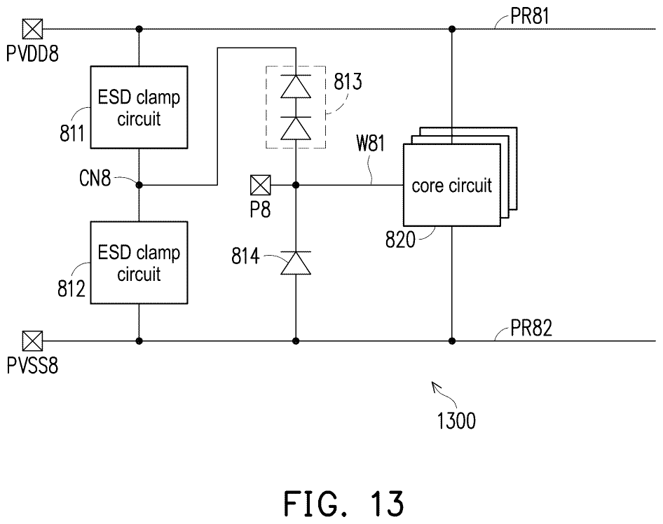

FIG. 13 is a schematic circuit block diagram of the pull-up element 813 according to an embodiment of the disclosure. When the pull-up element 813 shown in FIG. 13 is used as one of the many embodiments of the pull-up element 813 shown in FIG. 12, an integrated circuit 1300 shown in FIG. 13 may refer to the relevant description of the integrated circuit 1200 shown in FIG. 12.

In the embodiment shown in FIG. 13, the pull-up element 813 includes a diode string formed by the diodes that are stacked or connected in series. The number of diodes in the diode string may be determined according to the actual design. A cathode of the diode string is coupled to the common node CN8. An anode of the diode string is coupled to the signal transmission wire W81. A forward bias voltage difference of the diode string is greater than a voltage swing of the signal connection pad P8, which can avoid erroneous operation (an ESD protection mechanism).

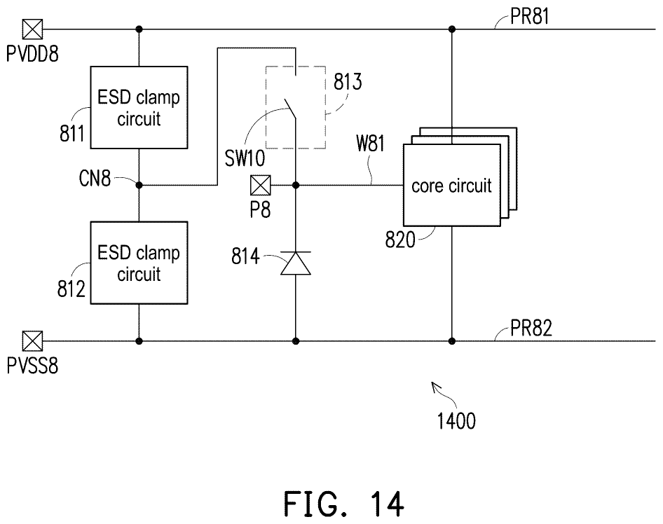

FIG. 14 is a schematic circuit block diagram of a pull-up element 813 according to another embodiment of the disclosure. When the pull-up element 813 shown in FIG. 14 is used as one of the many embodiments of the pull-up element 813 shown in FIG. 12, an integrated circuit 1400 shown in FIG. 14 may refer to the relevant description of the integrated circuit 1200 shown in FIG. 12.

In the embodiment shown in FIG. 14, the pull-up element 813 includes a bidirectional switch element SW10. The first terminal of the bidirectional switch element SW10 is coupled to the common node CN8. The second terminal of the bidirectional switch element SW10 is coupled to the signal transmission wire W81. When no ESD event occurs (a normal operating state) on the signal connection pad P8, the bidirectional switch element SW10 is turned off. When the ESD event occurs, at least one of the bidirectional switch element SW10 and the pull-down element 814 is turned on (or breakdowns) to discharge the ESD current of the ESD event. The bidirectional switch element SW10 may be deduced by referring to the relevant description of the bidirectional switch element SW2 shown in FIG. 2A or FIG. 2B or the bidirectional switch element SW31 shown in FIG. 3.

For example, the bidirectional switch element SW4 shown in FIG. 4 may also be used as one of many embodiments of the bidirectional switch element SW10 shown in FIG. 14 (in this case, the wire W41 and the wire W42 shown in FIG. 4 may be respectively regarded as the common node CN8 and the signal transmission wire W81 shown in FIG. 14). Alternatively, the bidirectional switch element SW5 shown in FIG. 5 or FIG. 6 may also be used as one of many embodiments of the bidirectional switch element SW10 shown in FIG. 14 (in this case, the wire W51 and the wire W52 shown in FIG. 5 or 6 may be respectively regarded as the common node CN8 and the signal transmission wire W81 shown in FIG. 14). Alternatively, the bidirectional switch element SW7 shown in FIG. 7 may also be used as one of the many embodiments of the bidirectional switch element SW10 shown in FIG. 14 (in this case, the wire W71 and the wire W72 shown in FIG. 7 may be respectively regarded as the common node CN8 and signal transmission wire W81 shown in FIG. 14).

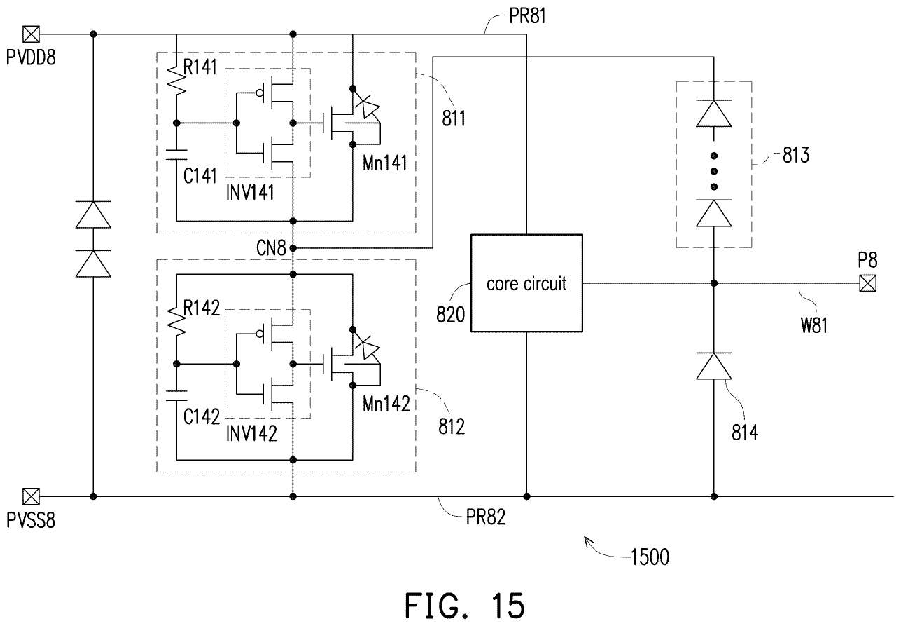

FIG. 15 is a circuit block diagram of the ESD clamp circuits 811 and 812 according to an embodiment of the disclosure. The ESD clamp circuits 811 and 812 shown in FIG. 15 may be used as one of many implementation examples of the ESD clamp circuits 811 and 812 shown in FIG. 12. An integrated circuit 1500 shown in FIG. 15 may be deduced by referring to the relevant description of the integrated circuit 1200 shown in FIG. 12, and therefore is not repeated herein.

In the embodiment shown in FIG. 15, the ESD clamp circuit 811 includes a resistor R141, a capacitor C141, an inverter INV141, and a switch transistor Mn141. The base of the switch transistor Mn141 is coupled to the common node CN8. The base of the switch transistor Mn141 is also coupled to the power rail PR81 through the parasitic diode. The control terminal of the switch transistor Mn141 is coupled to the output terminal of the inverter INV141. The power terminal of the inverter INV141 is coupled to the power rail PR81. The reference terminal of the inverter INV141 is coupled to the common node CN8. The first terminal of the resistor R141 is coupled to the power rail PR81. The second terminal of the resistor R141 and the first terminal of the capacitor C141 are coupled to the input terminal of the inverter INV141. The second terminal of the capacitor C141 is coupled to the common node CN8.

The ESD clamp circuit 812 includes a resistor R142, a capacitor C142, an inverter INV142, and a switch transistor Mn142. The base of the switch transistor Mn142 is coupled to the power rail PR82. The base of the switch transistor Mn142 is also coupled to the common node CN8 through the parasitic diode. The control terminal of the switch transistor Mn142 is coupled to the output terminal of the inverter INV142. The power terminal of the inverter INV142 is coupled to the common node CN8. The reference terminal of the inverter INV142 is coupled to the power rail PR82. The first terminal of the resistor R142 is coupled to the common node CN8. The second terminal of the resistor R142 and the first terminal of the capacitor C142 are coupled to the input terminal of the inverter INV142. The second terminal of the capacitor C142 is coupled to the power rail PR82.

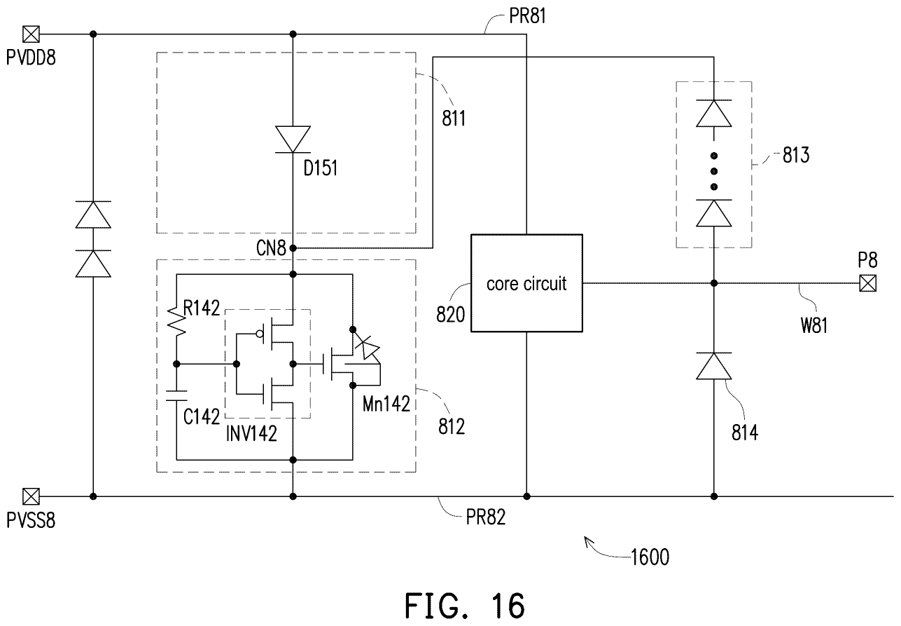

FIG. 16 is a circuit block diagram of the ESD clamp circuits 811 and 812 according to another embodiment of the disclosure. The ESD clamp circuits 811 and 812 shown in FIG. 16 may be used as one of many implementation examples of the ESD clamp circuits 811 and 812 shown in FIG. 12. An integrated circuit 1600 shown in FIG. 16 may be deduced by referring to the relevant description of the integrated circuit 1200 shown in FIG. 12 and the integrated circuit 1500 shown in FIG. 15, and therefore is not repeated herein.

The ESD clamp circuit 812 shown in FIG. 16 may be deduced by referring to the relevant description of the ESD clamp circuit 812 shown in FIG. 15, and therefore is not repeated herein. In the embodiment shown in FIG. 16, the ESD clamp circuit 811 includes a diode D151. The cathode of the diode D151 is coupled to common node CN8. The anode of the diode D151 is coupled to the power rail PR81.

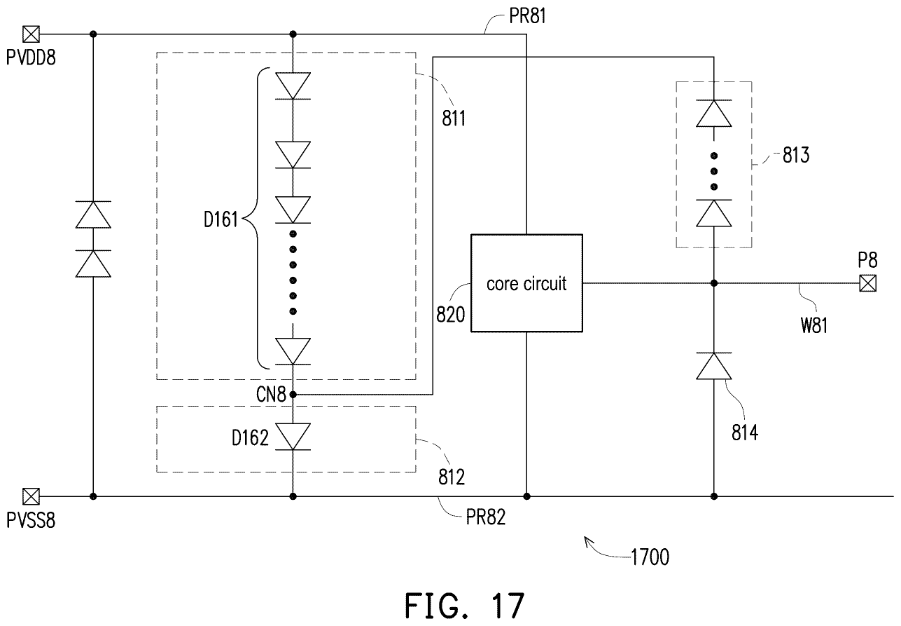

FIG. 17 is a circuit block diagram of the ESD clamp circuits 811 and 812 according to yet another embodiment of the disclosure. The ESD clamp circuits 811 and 812 shown in FIG. 17 may be used as one of many implementation examples of the ESD clamp circuits 811 and 812 shown in FIG. 12. An integrated circuit 1700 shown in FIG. 17 may be deduced by referring to the relevant description of the integrated circuit 1200 shown in FIG. 12, and therefore is not repeated herein.

In the embodiment shown in FIG. 17, the ESD clamp circuit 811 includes a diode string D161, and the ESD clamp circuit 812 includes a diode D162. The anode of the diode string D161 is coupled to the power rail PR81. The number of diodes in the diode string D161 may be determined according to the actual design. The cathode of the diode string D161 and the anode of the diode D162 are coupled to a common node CN8. The cathode of the diode D162 is coupled to the power rail PR82.

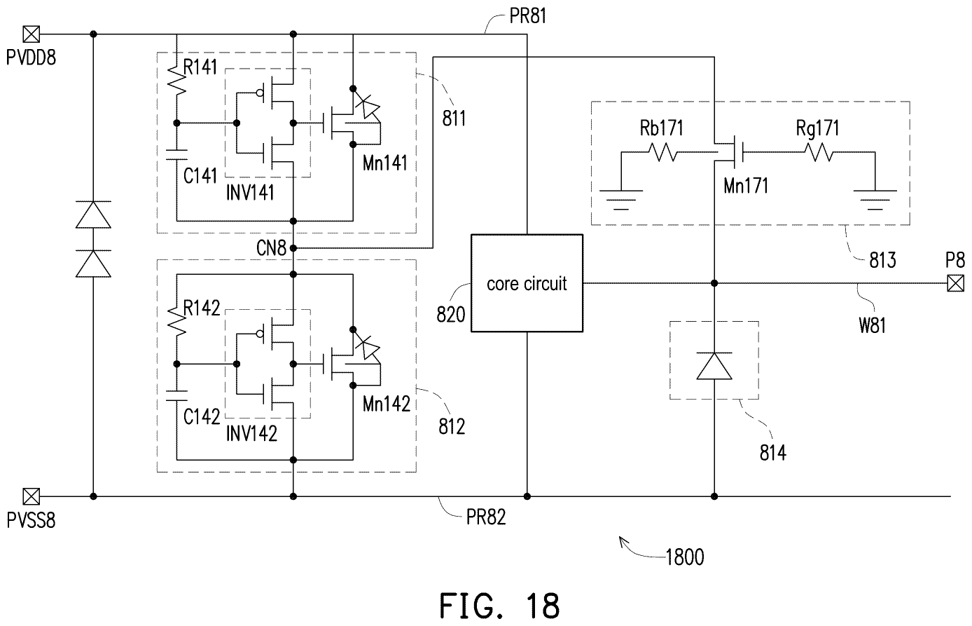

FIG. 18 is a schematic circuit block diagram of the pull-up element 813 and the pull-down element 814 according to an embodiment of the disclosure. The pull-up element 813 and the pull-down element 814 shown in FIG. 18 may be used as one of many implementation examples of the pull-up element 813 and the pull-down element 814 shown in FIG. 12. An integrated circuit 1800 shown in FIG. 18 may be deduced by referring to the relevant description of the integrated circuit 1200 shown in FIG. 12, and therefore is not repeated herein.

The ESD clamp circuits 811 and 812 shown in FIG. 18 may be deduced by referring to the relevant description of the ESD clamp circuits 811 and 812 shown in FIG. 15, and therefore is not repeated herein. In the embodiment shown in FIG. 18, the pull-up element 813 includes a switch transistor Mn171, a resistor Rg171, and a resistor Rb171. The first terminal (e.g., the drain) of the switch transistor Mn171 is coupled to the common node CN8. The second terminal (e.g., the source) of the switch transistor Mn171 is coupled to the signal transmission wire W81.

The base of the switch transistor Mn171 is coupled to the reference voltage (e.g., the ground voltage) through the resistor Rb171. The control terminal (e.g., the gate) of the switch transistor Mn171 is coupled to the control voltage (e.g., the ground voltage or other shutdown voltage) through the resistor Rg171 to turn off the switch transistor Mn171. That is, the first terminal of the resistor Rg171 is coupled to the control terminal of the switch transistor Mn171, and the second terminal of the resistor Rg171 is coupled to the control voltage (e.g., the shutdown voltage). When the ESD event does not occur (in the normal operation), the control voltage may turn off the switch transistor Mn171. When the ESD event occurs, the switch transistor Mn171 breakdowns to discharge the ESD current of the ESD event from the signal transmission wire W81 to the common node CN8 (or from the common node CN8 to the signal transmission wire W81).

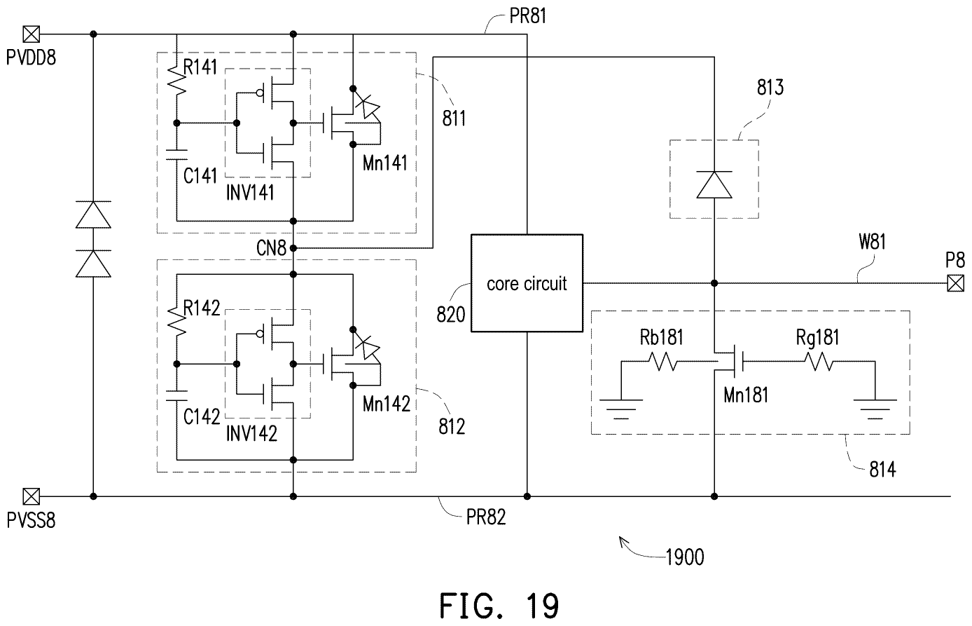

FIG. 19 is a schematic circuit block diagram of the pull-up element 813 and the pull-down element 814 according to yet another embodiment of the disclosure. The pull-up element 813 and the pull-down element 814 shown in FIG. 19 may be used as one of many implementation examples of the pull-up element 813 and the pull-down element 814 shown in FIG. 12. An integrated circuit 1900 shown in FIG. 19 may be deduced by referring to the relevant description of the integrated circuit 1200 shown in FIG. 12, and therefore is not repeated herein.

The ESD clamp circuits 811 and 812 shown in FIG. 19 may be deduced by referring to the relevant description of the ESD clamp circuits 811 and 812 shown in FIG. 15, and therefore is not repeated herein. In the embodiment shown in FIG. 19, the pull-down element 814 includes a switch transistor Mn181, a resistor Rg181, and a resistor Rb181. The first terminal (e.g., the drain) of the switch transistor Mn181 is coupled to the signal transmission wire W81. The second terminal (e.g., the source) of the switch transistor Mn171 is coupled to the power rail PR82. Although in the embodiment shown in FIG. 19, the pull-down element 814 includes a single switch transistor Mn181, the number of the switch transistors of the pull-down element 814 may be determined according to the actual design. For example, in other embodiments, the pull-down element 814 may include the switch transistors, and the switch transistors are stacked with each other or connected in series between the signal transmission wire W81 and the power rail PR82.

The base of the switch transistor Mn181 is coupled to the reference voltage (e.g., the ground voltage) through the resistor Rb181. The control terminal (such as the gate) of the switch transistor Mn181 is coupled to the control voltage (e.g., the ground voltage or other shutdown voltage) through the resistor Rg181 to turn off the switch transistor Mn181. That is, the first terminal of the resistor Rg181 is coupled to the control terminal of the switch transistor Mn181, and the second terminal of the resistor Rg181 is coupled to the control voltage (e.g., the shutdown voltage). When the ESD event does not occur (in the normal operation), the control voltage can turn off the switch transistor Mn181. When an ESD event occurs, the switch transistor Mn181 breakdowns to discharge the ESD current of the ESD event from the signal transmission wire W81 to the power rail PR82 (or from the power rail PR82 to the signal transmission wire W81).

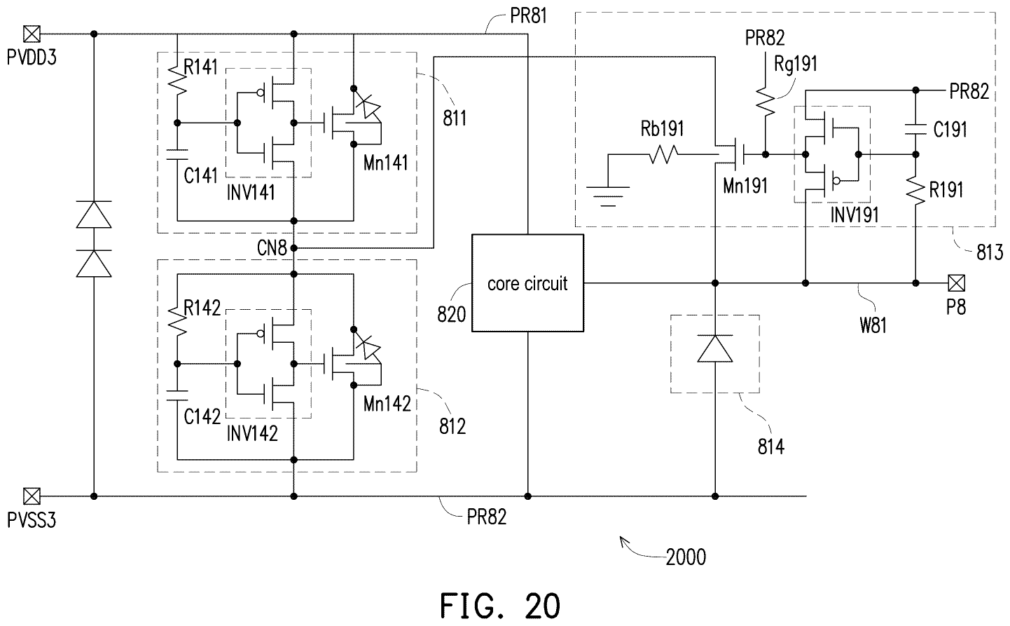

FIG. 20 is a schematic circuit block diagram of the pull-up element 813 and the pull-down element 814 according to yet another embodiment of the disclosure. The pull-up element 813 and the pull-down element 814 shown in FIG. 20 may be used as one of many implementation examples of the pull-up element 813 and the pull-down element 814 shown in FIG. 12. An integrated circuit 2000 shown in FIG. 20 may be deduced by referring to the relevant description of the integrated circuit 1200 shown in FIG. 12 and the control circuit 520 shown in FIG. 6, and therefore is not repeated herein.

The ESD clamp circuits 811 and 812 shown in FIG. 20 may be deduced by referring to the relevant description of the ESD clamp circuits 811 and 812 shown in FIG. 15, and therefore is not repeated herein. In the embodiment shown in FIG. 20, the pull-up element 813 includes a resistor R191, a capacitor C191, an inverter INV191, a switch transistor Mn191, a resistor Rg191, and a resistor Rb191. The control terminal of the switch transistor Mn191 is coupled to the output terminal of the inverter INV191. The power terminal of the inverter INV191 is coupled to the signal transmission wire W81. The reference terminal of inverter INV191 is coupled to power rail PR82. The first terminal of the resistor R191 is coupled to the signal transmission wire W81. The second terminal of the resistor R191 and the first terminal of the capacitor C191 are coupled to the input terminal of the inverter INV191. The second terminal of the capacitor C191 is coupled to the power rail PR82.

The base of the switch transistor Mn191 is coupled to the reference voltage (e.g., the ground voltage) through the resistor Rb191. The control terminal of the switch transistor Mn191 is coupled to the power rail PR82 through the resistor Rg191. The first terminal (e.g., the drain) of the switch transistor Mn191 is coupled to the common node CN8. The second terminal (e.g., the source) of the switch transistor Mn191 is coupled to the signal transmission wire W81. When the ESD event does not occur (in the normal operation), the switch transistor Mn191 is turned off. When the ESD event occurs, the switch transistor Mn191 is turned on to discharge the ESD current of the ESD event from the signal transmission wire W81 to the common node CN8 (or from the common node CN8 to the signal transmission wire W81).

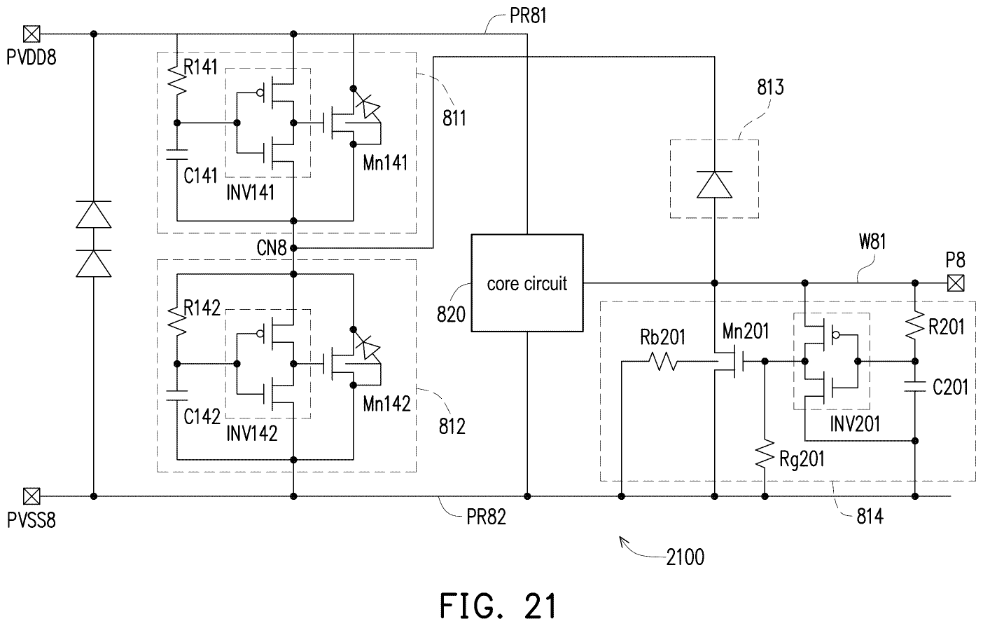

FIG. 21 is a schematic circuit block diagram of the pull-up element 813 and the pull-

down element 814 according to yet another embodiment of the disclosure. The pull-up element 813 and the pull-down element 814 shown in FIG. 21 may be used as one of many implementation examples of the pull-up element 813 and the pull-down element 814 shown in FIG. 12. An integrated circuit 2100 shown in FIG. 21 may be deduced by referring to the relevant description of the integrated circuit 1200 shown in FIG. 12 and the control circuit 520 shown in FIG. 6, and therefore is not repeated herein.

The ESD clamp circuits 811 and 812 shown in FIG. 21 may refer to the relevant description of the ESD clamp circuits 811 and 812 shown in FIG. 15 and make analogies, so the details will not be described again. In the embodiment shown in FIG. 21, the pull-down element 814 includes a resistor R201, a capacitor C201, an inverter INV201, a switch transistor Mn201, a resistor Rg201, and a resistor Rb201. The control terminal of the switch transistor Mn201 is coupled to the output terminal of the inverter INV201. The power terminal of the inverter INV201 is coupled to the signal transmission wire W81. The reference terminal of the inverter INV201 is coupled to the power rail PR82. The first terminal of the resistor R201 is coupled to the signal transmission wire W81. The second terminal of the resistor R201 and the first terminal of the capacitor C201 are coupled to the input terminal of the inverter INV201. The second terminal of the capacitor C201 is coupled to the power rail PR82.

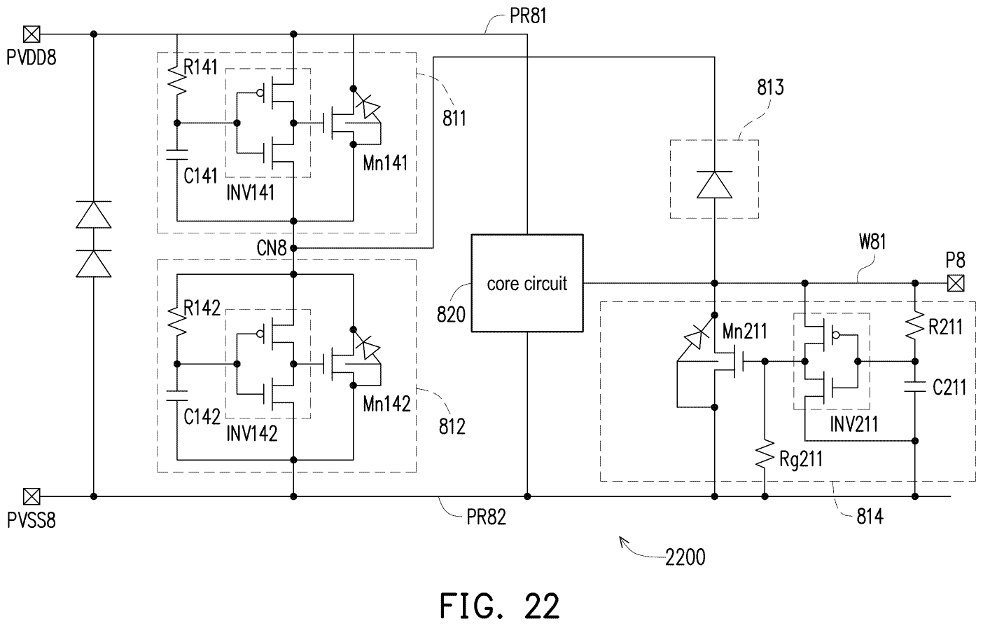

The base of switch transistor Mn201 is coupled to the power rail PR82 through the resistor Rb201. The control terminal of the switch transistor Mn201 is coupled to the power rail PR82 through the resistor Rg201. The first terminal (e.g., the drain) of the switch transistor Mn201 is coupled to the signal transmission wire W81. The second terminal (e.g., the source) of the switch transistor Mn201 is coupled to the power rail PR82. When the ESD event does not occur (in the normal operation), the switch transistor Mn201 is turned off. When the ESD event occurs, the switch transistor Mn201 is turned on to discharge the ESD current of the ESD event from the signal transmission wire W81 to the power rail PR82 (or from the power rail PR82 to the signal transmission wire W81). FIG. 22 is a schematic circuit block diagram of the pull-up element 813 and the pull-down element 814 according to another embodiment of the disclosure. The pull-up element 813 and the pull-down element 814 shown in FIG. 22 may be used as one of many implementation examples of the pull-up element 813 and the pull-down element 814 shown in FIG. 12. An integrated circuit 2200 shown in FIG. 22 may be deduced by referring to the relevant description of the integrated circuit 1200 shown in FIG. 12 and the control circuit 520 shown in FIG. 6, and therefore is not repeated herein.

The ESD clamp circuits 811 and 812 shown in FIG. 22 may be deduced by referring to the relevant description of the ESD clamp circuits 811 and 812 shown in FIG. 15, and therefore is not repeated herein. In the embodiment shown in FIG. 22, the pull-down element 814 includes a resistor R211, a capacitor C211, an inverter INV211, a switch transistor Mn211, and a resistor Rg211. The control terminal of the switch transistor Mn211 is coupled to the output terminal of the inverter INV211. The power terminal of the inverter INV211 is coupled to the signal transmission wire W81. The reference terminal of the inverter INV211 is coupled to the power rail PR82. The first terminal of the resistor R211 is coupled to the signal transmission wire W81. The second terminal of the resistor R211 and the first terminal of the capacitor C211 are coupled to the input terminal of the inverter INV211. The second terminal of capacitor C211 is coupled to the power rail PR82.

The base of the switch transistor Mn211 is coupled to the power rail PR82. The base of the switch transistor Mn211 is also coupled to the signal transmission wire W81 through the parasitic diode. The control terminal of the switch transistor Mn211 is coupled to the power rail PR82 through the resistor Rg211. The first terminal (e.g., the drain) of the switch transistor Mn211 is coupled to the signal transmission wire W81. The second terminal (e.g., the source) of the switch transistor Mn211 is coupled to the power rail PR82. When the ESD event does not occur (in the normal operation), the switch transistor Mn211 is turned off. When the ESD event occurs, the switch transistor Mn211 is turned on to discharge the ESD current of the ESD event from the signal transmission wire W81 to the power rail PR82 (or from the power rail PR82 to the signal transmission wire W81).

Although the pull-up element 813 in the embodiment shown in FIG. 18 includes a single switch transistor Mn171, the pull-up element 813 in the embodiment shown in FIG. 20 includes a single switch transistor Mn191, the pull-down element 814 in the embodiment shown in FIG. 21 includes a single switch transistor Mn201, and the pull-down element 814 in the embodiment shown in FIG. 22 includes a single switch transistor Mn211, the number of the switch transistors of the pull-up element 813 and the pull-down element 814 may be determined according to the actual design. For example, in other embodiments, the pull-up element 813 or the pull-down element 814 may include multiple switch transistors, the switch transistors are stacked with each other or connected in series between the signal transmission wire W81 and the common node CN8 or between the signal transmission wire W81 and the power rail PR82.

In summary, the first terminal of the pull-up element 813 is coupled to the common node CN8 between the ESD clamp circuits 811 and 812. When the ESD event occurs on the signal connection pad P8, the ESD clamp circuit 811 and the pull-up element 813 may immediately guide the ESD charge of the signal connection pad P8 to the power rail PR81, or the ESD clamp circuit 812 and the pull-up element 813 may immediately guide the ESD charge of the signal connection pad P8 to the power rail PR82. Alternatively, the pull-down element 814 may directly guide the ESD charge of the signal connection pad P8 to the power rail PR82 to prevent ESD stress from damaging the core circuit 820. However, in the initial state of the system, the rising point of the system power supply voltage (such as the VDD or other power voltage) of the power rail PR81 may be later than the rising point of the voltage of the signal connection pad P8. When the voltage of the power rail PR81 is lower than the voltage of the signal connection pad P8 in the initial state of the system, the ESD clamp circuit 812 and the pull-up element 813 may clamp the voltage of the signal connection pad P8 to prevent the charge of the signal connection pad P8 from leaking to the power rail PR81.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. An electrostatic discharge protection device configured to protect a core circuit coupled between a first power rail and a second power rail, wherein the electrostatic discharge protection device comprises:
a first electrostatic discharge clamp circuit coupled between the first power rail and a common node;
a second electrostatic discharge clamp circuit coupled between the common node and the second power rail; and
a pull-up element, wherein a first terminal of the pull-up element is coupled to the common node, and a second terminal of the pull-up element is coupled to a signal transmission wire, wherein the core circuit is coupled to a signal connection pad through the signal transmission wire.

2. The electrostatic discharge protection device according to claim 1, wherein the common node is only coupled to the first electrostatic discharge clamp circuit, the second electrostatic discharge clamp circuit, and the pull-up element.

3. The electrostatic discharge protection device according to claim 1, wherein,
in response to a electrostatic discharge positive pulse occurring on the first power rail and the signal connection pad being grounded, or in response to a electrostatic discharge negative pulse occurring on the signal connection pad and the first power rail being grounded, the first electrostatic discharge clamp circuit and the pull-up element jointly form a first electrostatic discharge path from the first power rail to the signal connection pad.

4. The electrostatic discharge protection device according to claim 3, further comprising:
a pull-down element, wherein a first terminal of the pull-down element is coupled to the signal transmission wire, a second terminal of the pull-down element is coupled to the second power rail, and
in response to the electrostatic discharge positive pulse occurring on the first power rail and the signal connection pad being grounded, or in response to the electrostatic discharge negative pulse occurring on the signal connection pad and the first power rail being grounded, the first electrostatic discharge clamp circuit, the second electrostatic discharge clamp circuit, the second power rail, and the pull-down element jointly form a second electrostatic discharge path from the first power rail to the signal connection pad.

5. The electrostatic discharge protection device according to claim 4, wherein an activation voltage of the first electrostatic discharge path is lower than the activation voltage of the second electrostatic discharge path.

6. The electrostatic discharge protection device according to claim 1, wherein in response to an electrostatic discharge event occurring on the signal connection pad, the pull-up element is turned on, and an electrostatic discharge current of the electrostatic discharge event passes through one of the first electrostatic discharge clamp circuit and the second electrostatic discharge clamp circuit.

7. The electrostatic discharge protection device according to claim 1, wherein the pull-up element comprises:
a diode string, wherein a cathode of the diode string is coupled to the common node, and an anode of the diode string is coupled to the signal transmission wire, wherein a forward bias voltage difference of the diode string is greater than a voltage swing of the signal connection pad.

8. The electrostatic discharge protection device according to claim 1, wherein the pull-up element comprises:
a switch transistor, wherein a first terminal of the switch transistor is coupled to the common node, and a second terminal of the switch transistor is coupled to the signal transmission wire.

9. The electrostatic discharge protection device according to claim 8 further comprising:
a control circuit coupled to a control terminal of the switch transistor, wherein the control circuit comprises a detection circuit, the detection circuit is coupled to the control terminal of the switch transistor, the detection circuit is configured to detect the signal connection pad,
in response to an electrostatic discharge event occurring, the detection circuit turns on the switch transistor; and
in response to the electrostatic discharge event not occurring, the detection circuit turns off the switch transistor.

10. The electrostatic discharge protection device according to claim 8 further comprising:
a control circuit coupled to a control terminal of the switch transistor, wherein the control circuit comprises a bias circuit, the bias circuit is coupled to the control terminal of the switch transistor,
in response to an electrostatic discharge event occurring, the bias circuit causes the control terminal of the switch transistor to be in an electrically floating state; and
in response to the electrostatic discharge event not occurring, the bias circuit provides a bias voltage to the control terminal of the switch transistor to turn off the switch transistor.

11. The electrostatic discharge protection device according to claim 8, wherein the pull-up element further comprises:
a resistor, wherein a first terminal of the resistor is coupled to a control terminal of the switch transistor, and a second terminal of the resistor is coupled to a control voltage or a control circuit to turn off the switch transistor.

12. The electrostatic discharge protection device according to claim 8, wherein,
in response to an electrostatic discharge event occurring, the switch transistor is turned on to discharge an electrostatic discharge current of the electrostatic discharge event; and
in response to the electrostatic discharge event not occurring, the switch transistor is turned off.

13. The electrostatic discharge protection device according to claim 12, wherein the pull-up element further comprises:
a resistor, wherein a first terminal of the resistor is coupled to a control terminal of the switch transistor, and a second terminal of the resistor is coupled to a detection circuit to turn off the switch transistor, the detection circuit is coupled to the second terminal of the resistor, the detection circuit is configured to detect the signal connection pad,
in response to an electrostatic discharge event occurring, the detection circuit turns on the switch transistor; and
in response to the electrostatic discharge event not occurring, the detection circuit turns off the switch transistor.

14. The electrostatic discharge protection device according to claim 12, wherein the pull-up element further comprises:
a resistor, wherein a first terminal of the resistor is coupled to a control terminal of the switch transistor, and a second terminal of the resistor is coupled to a bias circuit to turn off the switch transistor, and the bias circuit is coupled to the second terminal of the resistor,
in response to an electrostatic discharge event occurring, the bias circuit causes the control terminal of the switch transistor to be in an electrically floating state; and
in response to the electrostatic discharge event not occurring, the bias circuit provides a bias voltage to the control terminal of the switch transistor to turn off the switch transistor.

15. The electrostatic discharge protection device according to claim 8, wherein,
in response to an electrostatic discharge event occurring, the switch transistor breakdowns to discharge an electrostatic discharge current of the electrostatic discharge event; and
in response to the electrostatic discharge event not occurring, the switch transistor is turned off.

16. The electrostatic discharge protection device according to claim 15, wherein the control terminal of the switch transistor is coupled to a shutdown voltage to turn off the switch transistor.

17. The electrostatic discharge protection device according to claim 15, wherein the pull-up element further comprises:
a detection circuit coupled to the control terminal of the switch transistor, wherein the detection circuit is configured to detect the signal connection pad,
in response to an electrostatic discharge event occurring, the detection circuit turns off the switch transistor; and
in response to the electrostatic discharge event not occurring, the detection circuit turns off the switch transistor.

18. The electrostatic discharge protection device according to claim 8, wherein the pull-up element further comprises:
a control circuit coupled to a base of the switch transistor; and
a resistor, wherein the base of the switch transistor is coupled to the control circuit through the resistor.

19. The electrostatic discharge protection device according to claim 8, wherein the pull-up element further comprises:
a detection circuit coupled to the base of the switch transistor, wherein the detection circuit is configured to detect whether an electrostatic discharge event occurs on the signal connection pad to dynamically determine a voltage of the base of the switch transistor; or
a bias circuit coupled to the base of the switch transistor.

20. The electrostatic discharge protection device according to claim 8, wherein an operating voltage of the pull-up element is less than a power supply voltage of the core circuit.
